(19) United States
(12) Patent Application Publication
(10) Pub. No.: US 2026/0190530 A1
(43) Pub. Date: Jul. 2, 2026

(54) IMAGE SENSOR AND MANUFACTURING METHOD THEREOF

(71) Applicant: OMNIVISION TECHNOLOGIES, INC., Santa Clara, CA (US)

(72) Inventors: Alexander Kalnitsky, Toronto (CA); Vincent Venezia, Los Gatos, CA (US); Lindsay Alexander Grant, Campbell, CA (US)

(73) Assignee: OMNIVISION TECHNOLOGIES, INC., Santa Clara, CA (US)

(21) Appl. No.: 19/006,054

(22) Filed: Dec. 30, 2024

(51) Int. Cl. H10F 39/00; H10F 39/18

(52) U.S. Cl. CPC H10F 39/807; H10F 39/014; H10F 39/018; H10F 39/182; H10F 39/8067; H10F 39/809

(57) ABSTRACT

A manufacturing method of an image sensor includes the following steps. A semiconductor substrate having a frontside surface and a backside surface opposite to the frontside surface is provided. A photosensitive region is formed in the semiconductor substrate. A floating diffusion region is formed proximately to the photosensitive region for receiving image charges therefrom. A dielectric layer is formed on the frontside surface of the semiconductor substrate. A gate electrode is formed in the dielectric layer to couple the photosensitive region and the floating diffusion region. A deep trench isolation structure is formed adjacent to the photosensitive region through an etching process. The DTI structure extends from the dielectric layer on the frontside surface toward the backside surface of the semiconductor substrate. The DTI structure has an upper surface leveled with a top surface of the dielectric layer.

### TECHNICAL FIELD

The present disclosure relates to a manufacturing method of an image sensor having a deep trench isolation structure.

### BACKGROUND

In general, an image sensor includes a plurality of pixels arranged in a matrix and generates optical signals from the pixels to obtain a two-dimensional image signal. Therefore, in the pixels, photoelectric conversion elements that generate electric charges according to incident light are provided and circuits for outputting signals generated by the photoelectric conversion elements are provided.

Each pixel can take the following configuration. A photodiode is used as the photoelectric conversion element. Electric charges (e.g., electrons or holes) photo-generated by the photodiode in response to an incident light are transferred to a coupled floating diffusion via a transfer transistor. A signal of the floating diffusion is supplied to a gate of a source follower transistor that vary as a function of the incident light measured by the photodiode. An image signal from the source follower transistor is outputted to an output line via a selection transistor. In other words, the amount of image charge generated is proportional to the intensity of the image light, which is read out as analog image signals from the column bitlines and converted to digital values to provide information that is representative of the external scene.

The image sensor includes deep trench isolation structures disposed between the adjacent pixels to suppress cross talk (e.g., electrical and/or optics) between photodiodes. The deep trench isolation structure is filled with dielectric or polysilicon material. Nevertheless, the current DTI structure filled with dielectric or polysilicon material are not highly reflective and are some transparent in some extent. Accordingly, the DTI structure cannot effectively fulfill the requirements of excellent optical isolation and high reflectivity of the DTI filling material to redirect scattered photons back into the pixels.

### SUMMARY

A manufacturing method of an image sensor includes the following steps. A semiconductor substrate having a frontside surface and a backside surface opposite to the frontside surface is provided. A photosensitive region is formed in the semiconductor substrate. A floating diffusion region is formed proximately to the photosensitive region for receiving image charges therefrom. A gate electrode is formed adjacent to a lateral side of the photosensitive region. A deep trench isolation (DTI) structure is formed adjacent to the photosensitive region through an etching process. A dielectric layer (e.g., oxide-based material) is disposed on the frontside surface of the semiconductor substrate. The DTI structure extends from the dielectric layer on the frontside surface toward the backside surface of the semiconductor substrate. The DTI structure is filled with a reflective metal material therein. In some embodiments, the material filling process is performed on the frontside surface of the semiconductor substrate. In some embodiments, the material filling process is performed on the backside surface of the semiconductor substrate.

With the image sensor of the present disclosure, it is possible to form a deep trench isolation (DTI) structure that can achieve excellent electrical and optical isolation and redirect scattered photons back into the pixel by filling the DTI structure with the high reflective metal materials.

### BRIEF DESCRIPTION OF DRAWINGS

An embodiment of the present disclosure will be described based on the following figures, wherein:

FIG. 1 to FIG. 11 are schematic diagrams illustrating cross-sectional views of an exemplary formation process of deep trench isolation (DTI) structures of an image sensor in accordance with an embodiment of the present disclosure;

FIG. 12 is a schematic block diagram illustrating a formation process of DTI structures in accordance with an embodiment of the present disclosure;

FIG. 13 to FIG. 17 are schematic diagrams illustrating cross-sectional views of a formation process of a DTI structure of an image sensor after the formation step shown in FIG. 6 in accordance with another embodiment of the present disclosure;

FIG. 18 is a schematic block diagram illustrating a formation process of DTI structure in accordance with another embodiment of the present disclosure.

### DESCRIPTION OF EMBODIMENT

In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects. Note that the embodiment explained below does not limit the present disclosure. A configuration formed by selectively combining a plurality of illustrations is also included in the present disclosure.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

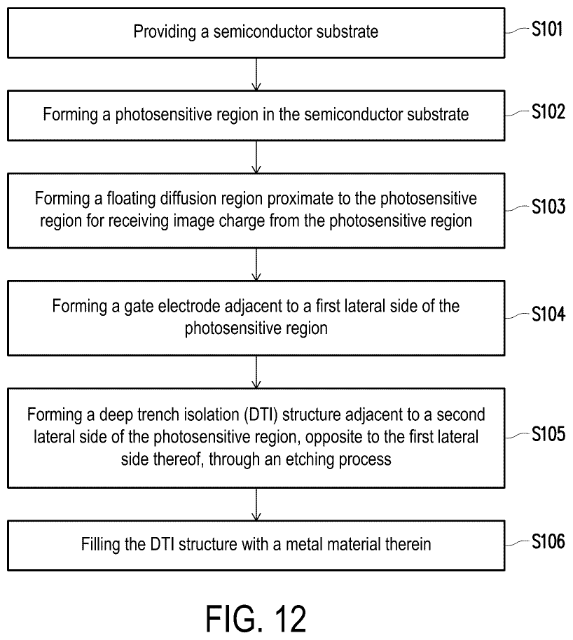

FIG. 1 to FIG. 11 are schematic diagrams illustrating cross-sectional views of a formation process of deep trench isolation (DTI) structures 160 of an image sensor 10 in accordance with an embodiment of the present disclosure. FIG. 12 is a schematic block diagram illustrating a formation process of DTI structures 160 in accordance with an embodiment of the present disclosure. As shown in FIG. 11, the DTI structures 160 may be used in image sensor chips (such as front-side illumination (FSI) image sensor chips or backside illumination (BSI) image sensor chips) in accordance with some embodiments.

Referring to FIG. 1 and the forming step S101 in FIG. 12, a semiconductor substrate 110 is provided. The semiconductor substrate 110 may comprise, for example, bulk silicon, doped or undoped, or an active layer of a semiconductor-on-insulator (SOI) substrate. The SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the semiconductor substrate 110 may include another elementary semiconductor, such as germanium, a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP, or combinations thereof. Other substrates, such as multi-layered or gradient substrates, may also be used.

The semiconductor substrate 110 has a frontside surface 111 and a backside surface 113 opposite to the frontside surface 111. The frontside surface 111 may be formed with active devices such as transistors thereon. As described in more specific below, in the current embodiment, the DTI structures 160 may be formed from the frontside surface 111 of the substrate 110. The skilled artisans would appreciate that in some embodiments similar methods can be also applied to DTI structures formed from the backside surface 113 of the substrate 110.

Referring again to FIG. 1 and the forming step 102 in FIG. 12, a photosensitive region 114 may be formed or otherwise disposed in the semiconductor substrate 110 and proximately to the frontside surface 111. The photosensitive region 114 may be included in a photosensitive device. In some embodiments, the photosensitive region 114 may be formed by, for example, implanting suitable ions. In some embodiments, the impurity ions may be implanted in an epitaxial layer 112 within the semiconductor substrate 110. In some embodiments, the epitaxial layer 112 may be formed on a base or bulk substrate. In some embodiments, the photosensitive region 114 is configured to convert light signals (e.g., photons) to electrical signals and may include PN junction photodiodes, PNP photo-transistors, NPN photo-transistors, and the like. In an illustrated embodiment, the photosensitive regions 114 may include an n-type doped region that is formed within a p-type semiconductor layer (e.g., at least a portion of the semiconductor substrate 110). In some embodiments, the p-type semiconductor layer may be the epitaxial layer 112. In some embodiments, the p-type semiconductor substrate may isolate and reduce electrical crosstalk between the adjacent photosensitive regions 114.

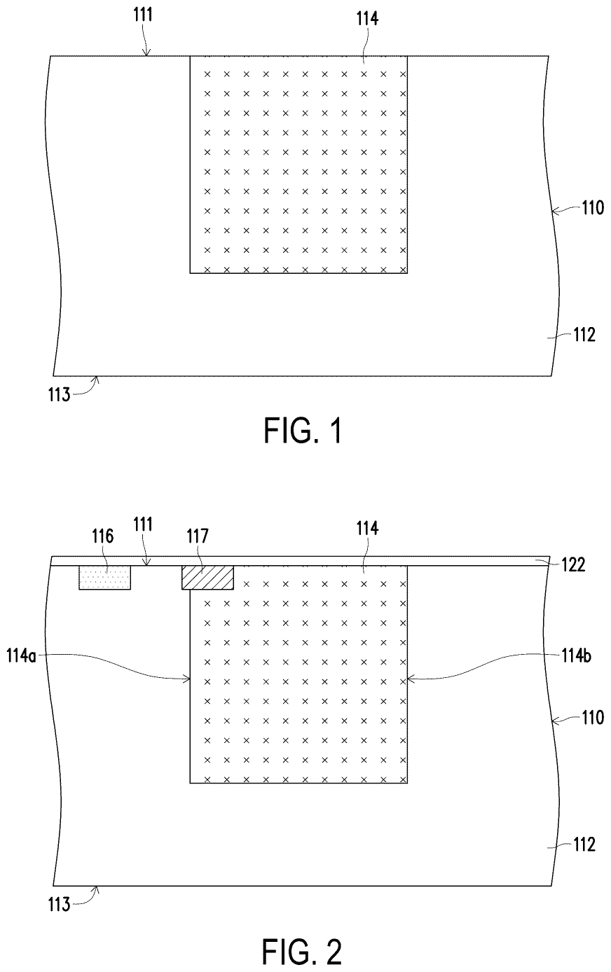

Referring to FIG. 2 and the forming step S103 in FIG. 12, in some embodiments, a light doped source/drain (LDD) region 117 are formed proximately to the frontside surface 111 of the semiconductor substrate 110 and adjacent to a first lateral side 114a of the photosensitive region 114. In some embodiments, a floating diffusion region 116 may include an N⁺ doped region, which may be formed by activating the dopant through an annealing process to improve the crystalline structure of material and may be configured for storing charge carriers transferred from the photodiode. In some embodiments, the light doped source/drain (LDD) region 117 may be formed or otherwise disposed between floating diffusion region 116 and the photosensitive region 114.

In some embodiments, a dielectric layer, for example, a high thermal oxide (HTO) layer 122 may be formed on the frontside surface 111 of the semiconductor substrate 110. In some embodiments, a selected thickness of the HTO layer 122 may be ranged from 5 nm to approximately 10 nm. In some embodiments, the HTO layer 122 may be formed of aluminum oxide (AlO), tantalum oxide (TaO), hafnium oxide (HfO), hafnium silicon oxide (HfSiO), hafnium aluminum oxide (HfAlO), or hafnium tantalum oxide (HMO), or the combination thereof.

Referring to FIG. 3, a gate dielectric 134 is formed within the HTO layer 122 through photolithography process such as masking and etching process. In the instant embodiment, referring to forming step S104 in FIG. 12, a gate electrode 132 may be formed on the gate dielectric 134 and between the floating diffusion region 116 and the photodiode of photosensitive region 114. As shown in FIG. 3, the gate dielectric 134 is disposed between the gate electrode 132 and frontside surface 111 of the semiconductor substrate 110, and the gate electrode 132 is proximate to the first lateral side 114a of the photosensitive region 114. The gate electrode 132 selectively couple the floating diffusion region 116 to the photodiode of photosensitive region 114 in response to a control voltage applied thereto. The gate electrode 132 in embodiments may serve as a transfer gate to transfer the charges photo generated by photodiode formed in the photosensitive region 114 to the floating diffusion region 116.

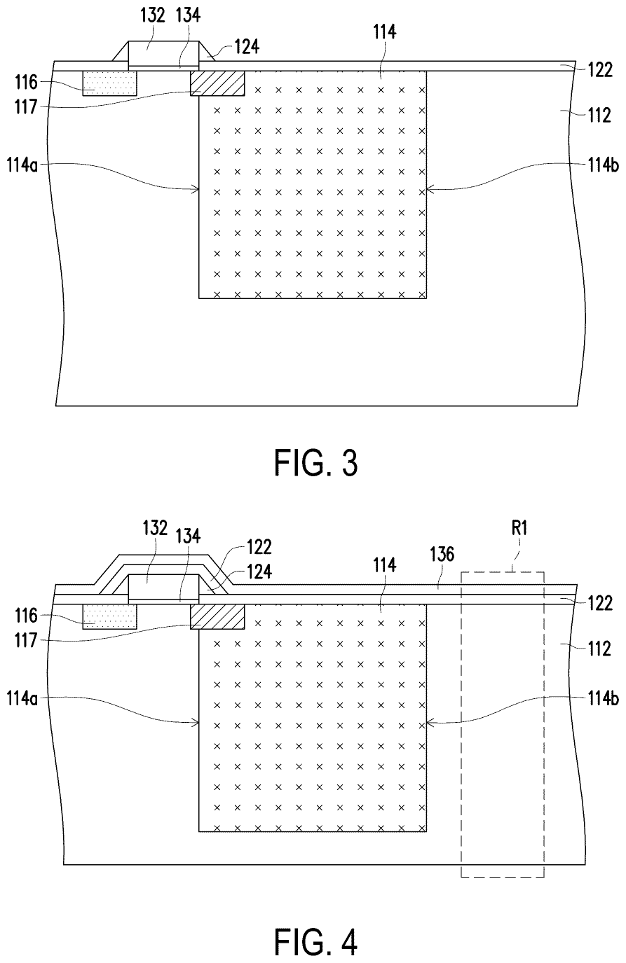

Referring again to FIG. 3, in some embodiments, sidewall spacers 124 may be formed to enclose sidewalls of the gate electrode 132. In some embodiments, the sidewall spacers 124 may be formed of, for example, a nitride film (e.g., silicon nitride, SiN). As shown in FIG. 4, both the gate electrode 132 and the sidewall spacers 124 may be further covered by the HTO layer 122. In some embodiments, another dielectric layer, for example, a nitride layer 136, formed of SiN, may be further formed and stacked on the HTO layer 122. In some embodiments, both the HTO layer 122 and the nitride layer 136 are blankly formed on the frontside surface 111 of the semiconductor substrate 110. The deposition of the nitride layer 136 can block oxidation of the source/drain regions, for example doped regions 116 or 117, and thus avoid oxidation enhanced diffusion from accruing during fabrication process such as annealing.

In the current embodiment, a deep trench isolation forming region R1 may be located within the semiconductor substrate 110 and adjacent to a second lateral side 114b of the photosensitive region 114 for subsequent processes of forming DTI structure 160.

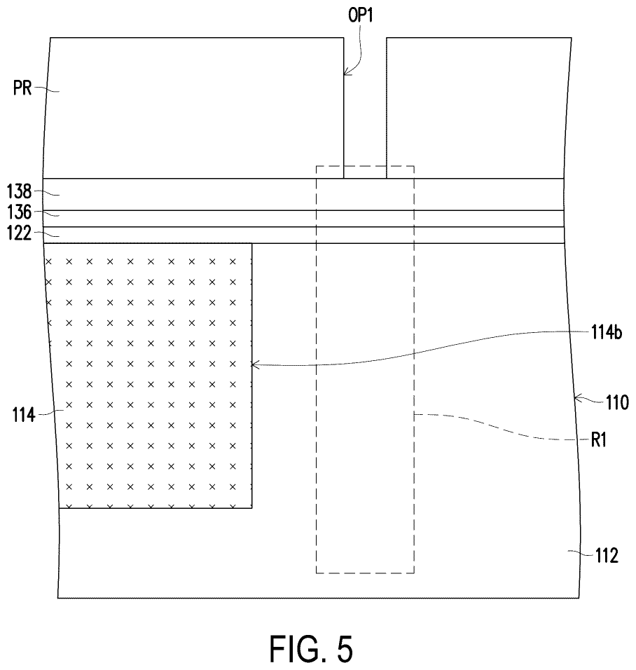

Referring to FIG. 5, an oxide layer 138 (second oxide layer) may be formed above the nitride layer 136 and the HTO layer 122 to form an oxide-nitride-oxide (ONO) stack. That is, the nitride layer 136 in embodiments is disposed between second oxide layer 138 and the HTO layer 122. In some embodiments, a photoresist film PR having a pattern of an opening OP disposed correspondingly above the forming region R1 may be blanketly coated (e.g., spin-coated) cover the above ONO stack. In some embodiments, the width of the opening OP may be approximately 10-20 microns. In embodiments, the photoresist film PR is used as a photomask to etch and pattern the underlying layers 122, 136, and 138 for forming DTI trench for DTI structure 160.

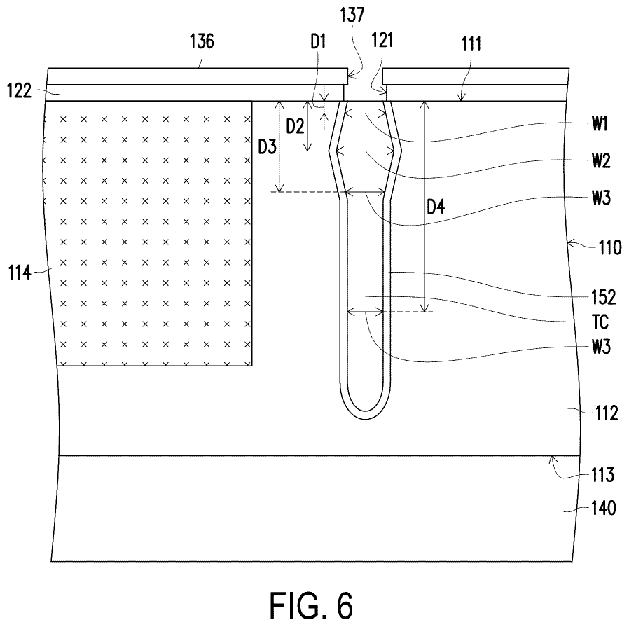

Referring to FIG. 5 and FIG. 6, the above ONO stack is etched, and the photoresist film PR is subsequently removed. As shown in FIG. 5 and FIG. 6, the forming region R1 is further etched by removing substrate material of semiconductor substrate 110 to form a trench cavity TC therewithin. In some embodiments, the semiconductor substrate 110 might be bonded to a wafer substrate, for example, a P⁺type substrate 140 after formication of the trench cavity TC. In some embodiments, a trench cavity TC may be etched to a depth extending slightly exceeding the remaining thickness of the semiconductor substrate 110 after the semiconductor substrate 110 bonded to the P⁺substrate 140 and thinned.

In the present embodiment, the trench cavity TC extends from the frontside surface 111 of the semiconductor substrate 110 into the semiconductor substrate 110 and toward the backside surface 113 of the semiconductor substrate 110. It is appreciated that the etching process of the semiconductor substrate 110 may be performed through acceptable etching processes, which may be performed at a relatively low temperature to reduce damage to other features (e.g., electrical components, interconnect structures, and the like) within the image sensor.

In some embodiments, the semiconductor substrate 110 is formed of silicon material. The etching process is performed using a dry etching method including, and not limited to, inductively coupled plasma (ICP), transformer coupled plasma (TCP), electron cyclotron resonance (ECR), reactive ion etch (RIE), and the like. The process gases include, for example, fluorine-containing gases (such as SF₆, CF₄, CHF₃, NF₃), chlorine-containing gases (such as Cl₂), Br₂, HBr, BCl₃ and/or the like. In some embodiments, the photoresist film PR is consumed during the above etching process. In other embodiments, remaining portions of the photoresist film PR may be, for example, removed in plasma ashing and/or wet strip processes. In the current etching process, the oxide layer 138 and the polymer residue on sidewalls of the trench cavity TC are removed through the dilute HF to expose the nitride layer 136 under the oxide layer 138.

In the current embodiment, as shown in FIG. 6, the etching process may slightly undercut the HTO layer 122 under the nitride layer 136. An opening 121(first opening) is formed in the HTO layer 122, which may have a width greater than that of an opening 137 (second opening) formed in the nitride layer 136. Referring to FIG. 6, after the etching process to form the trench cavity TC, the sidewalls of the trench cavity TC may be uniformly oxidized through an In Situ Steam Generator (ISSG) reactor (not illustrated) to form an oxidized layer 152. In the illustrated embodiment, the thickness of the oxidized layer 152 lined conformal to sidewalls of trench cavity may be ranged from approximately 5 to 15 nm. In the illustrated embodiment, the thermal cycle in the above oxidization process may be also utilized as a final activation annealing process for the doped regions 117 and floating diffusion region 116 shown in FIG. 4.

In some embodiments, the nitride layer 136 as shown in FIG. 6 may be optionally remained on the semiconductor substrate 110. In one embodiment, the nitride layer 136 may be left in place for formation of the sealed trench cavity TC in the case of trench filled from the backside surface 113 of the semiconductor substrate 110, which is further explained in the following paragraphs of the present disclosure. As shown in FIG. 6 and the formation process S105 in FIG. 12, the trench cavity TC may have a bow shape due to the etching process. That is, the trench cavity TC may include a neck portion having greater trench width than that of the rest portion thereof. In some embodiments, the trench cavity TC may be outwardly tapered from an upper portion thereof toward to the opening 121 of the HTO layer 122. Specifically, the trench cavity TC may have a first width W1 approximately from 70 nm to 150 nm at a first depth D1 tapered to the neck portion of the trench cavity TC having a second width W2 approximately from 80 nm to 170 nm at a second depth D2 greater than the first depth D1 with respect to frontside surface 111. In some embodiments, the trench cavity TC might be further inwardly tapered from the neck portion having second width W2 to a lower portion at a third depth D3 greater than the second depth D2 with respect to frontside surface 111, having a third width W3 approximately from 70 nm to 150 nm. As shown in FIG. 6, a trench width of the trench cavity TC at a depth further or greater from the third depth D3 with respect to frontside surface 111, for example, a fourth depth D4, may be constant with the third width W3 at the third depth D3.

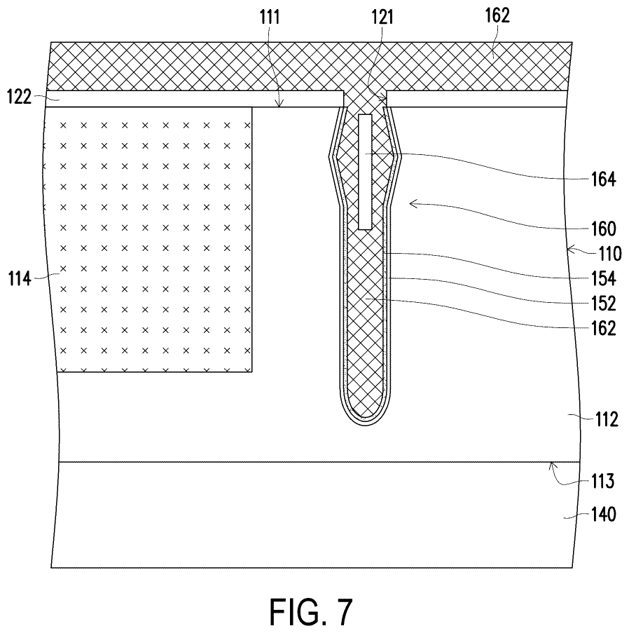

Referring to FIG. 7, in some embodiments, the nitride layer 136 may be removed though a hot phosphoric acid etching process to expose the opening 121 of the HTO layer 122. In addition, a high κ dielectric layer 154 with fixed negative charge may be deposited on the oxidized layer 152 on the sidewall of the trench cavity TC by, for example, an atomic layer deposition (ALD) process. The above process may be performed for forming a metal-oxide-semiconductor (MOS) structure with a higher threshold voltage Vt and may be for passivating the sidewall of the trench cavity TC. In the present embodiment, the high κ dielectric layer 154 with fixed negative charge disposed over the P⁻ silicon can attract holes close to the sidewall surfaces of the trench cavity TC forming hole accumulation or rich region passivating sidewall surfaces of the trench cavity TC, and thus an accumulation region of holes on the sidewalls of the trench cavity TC that otherwise need to be created by the sidewall doping may be created. Hence, high thermal process (greater than 700 degree Celsius), which may damage the device structure, may be no longer required.

Referring again to FIG. 7 and the formation step S106, in some embodiments, the trench cavity TC may be filled with a reflective metal material 162 having high reflectivity, such as aluminum. The reflective metal material 162 may be deposited to fill the trench cavity TC by a chemical vapor disposition (CVD) or the ALD process through the opening of the trench cavity TC exposed from the frontside surface 111 of the semiconductor substrate 110 to form a deep trench isolation (DTI) structure 160. As shown in FIG. 7, in the present embodiment, the reflective metal material 162 may also fill the opening 121 of the HTO layer 122 and blanketly cover the surface of the HTO layer 122. In some other embodiments, the reflective metal material 162 may also include silver (Ag) or other materials with high reflectivity.

It is appreciated that through deposition of the high reflective metal materials, such as Al or Ag, in the trench cavity TC for forming the DTI structure 160, the DTI structure 160 may achieve excellent electrical and optical isolation. Further, the high reflectivity of the reflective metal material 162 is capable of redirecting incident light back into the photosensitivity region 114 of the corresponding pixels. Hence, crosstalk between the pixels can be greatly reduced and avoided.

In some embodiments, during formation of the DTI structure 160, at least a process void 164 may be formed within the reflective metal material 162. It is noted that appearance of the process void 164 in the filled reflective metal material 162 may reduce inner stain thereof generated during the deposition process.

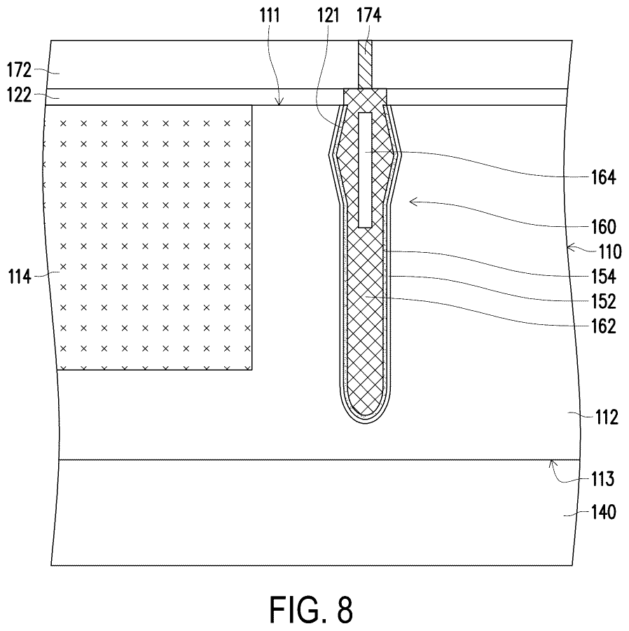

Referring to FIG. 8, an etch back process may be applied to a portion of reflective metal material 162 blanketly covering the HTO layer 122. A dielectric material layer 172 (e.g., intermetal dielectric (IMD) layer) is subsequently deposited over the HTO layer 122 and the filled reflective metal material 162 covering the opening 121 for subsequent processing. In some embodiments, a top or upper surface of the filled reflective metal material 162 is levelled or flush with the HTO layer 122. The dielectric layer 172 may be made of a dielectric material, such as silicon oxide, silicon nitride, silicon oxynitride, a spin-on dielectric material, or a low-k dielectric material. In some embodiments, the dielectric material layer 172 may be further etched and patterned to form an opening penetrating through the dielectric metal layer 172 for filling metal material therein to serve as metal contacts 174. The metal contacts 174 penetrating through the dielectric material layer 172 may be electrically connected to the transfer gate 132, the floating diffusion region 116, the LDD regions 117, and optionally the reflective metal material 162 filled in the DTI structure 160 respectively. The metal contacts 174 may couple the reflective metal material 162 filled in the DTI structure 160 to receive a bias voltage, such as negative bias voltage for sidewall surface passivation.

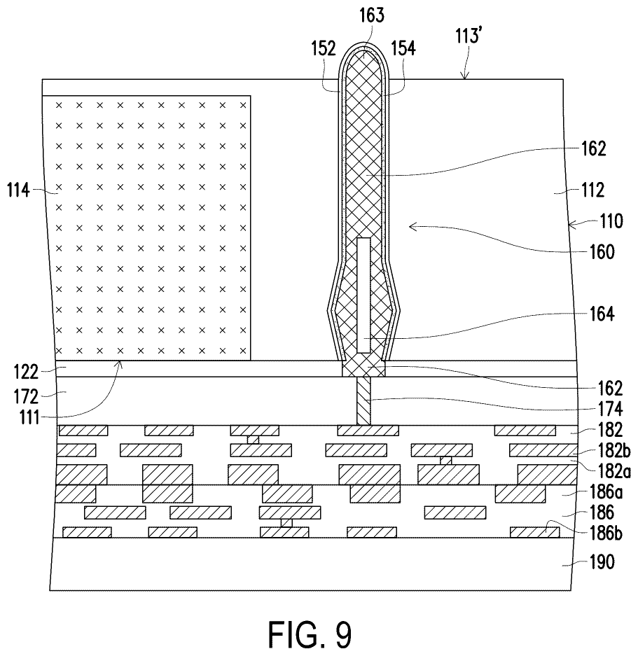

Referring to FIG. 9, the dielectric material layer 172 disposed over the semiconductor substrate 110 may be bonded to a logic substrate 190 (e.g., ASIC wafer) through bonding process via bonding layers 182 and 186 e.g., oxide boding or hybrid bonding. The bonding layers 182 and 186 may respectively include inter-level dielectric (ILD) layers 182a, 186a and metal layers 182b, 186b distributed therein. As shown in FIG. 8 and FIG. 9, a thinning process is performed to the P⁺ substrate 140 bonded to the backside surface 113 of the semiconductor substrate 110 through mechanical grinding and wet etching process and stopping on the semiconductor substrate 110 with a target thickness. Further, a dry etch process with high selectivity is performed to the backside surface 113 of the semiconductor substrate 110 for exposing a tip portion 163 of the backside of the DTI structure 160.

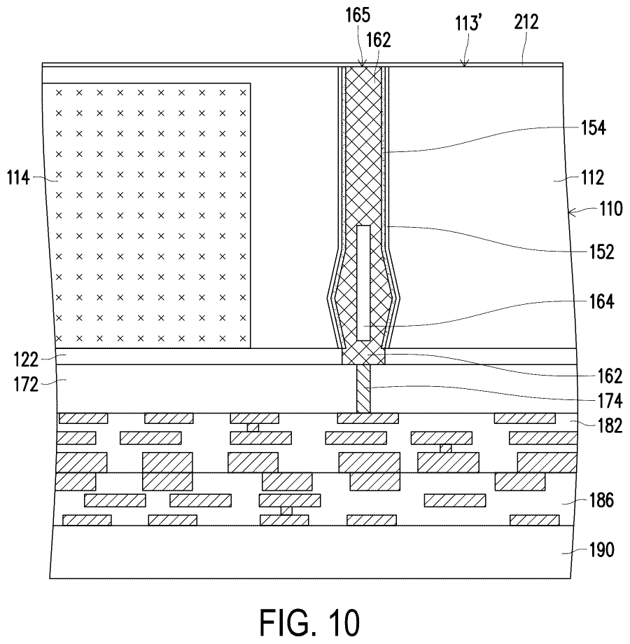

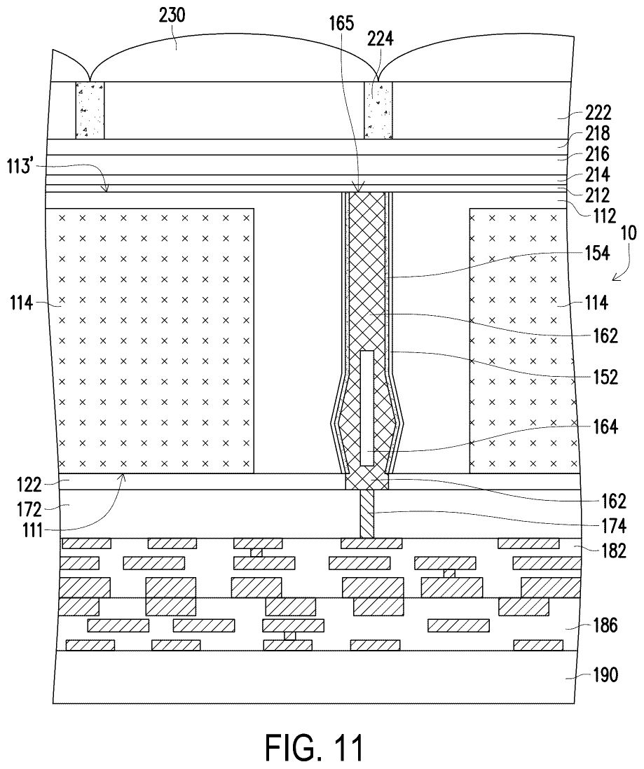

Referring to FIG. 10, a planarization process, for example chemical mechanical polishing (CMP) process, may be applied to remove the tip portion 163 of the backside of the DTI structure 160 and to the backside of the semiconductor substrate 110. By performing the above planarization process, the backside surface 113′ of the semiconductor substrate 110 formed through the process is coplanar or flush with a backside 165 of the DTI structure 160. As shown FIG. 10, a thin oxide layer 212 (first high κ dielectric layer) may be subsequently deposited on the backside surface 113′ and the backside 165 of the DTI structure 160 to passivate the backside surface 113′ of the semiconductor substrate 110.

Referring to FIG. 11, in some embodiments, another high κ dielectric layer 214 (second high κ dielectric layer) may be deposited on the high κ dielectric layer 212 (first high κ dielectric layer) to serve as an additional passivation layer. In some embodiments, a third high κ dielectric layer 216 may be formed on the second high κ dielectric layer 214 to serve as an anti-reflective layer for forming optical elements thereon.

As shown in FIG. 11, a buffer oxide layer 218 may be disposed on the anti-reflective layer 216 for preparation of a backside surface for depositing color filters 222 and composite grids 224 thereon. In some embodiments, the composite grids 224 may include a stack of metal grids and low-index (low-n) grids. In some embodiments, the low-n grids may include a low-n dielectric, such as an oxide (e.g., SiO₂) or hafnium oxide (e.g., HfO₂) or a material having a refractive index smaller than that of the color filters 222. The refractive index of the low-n grids is less than the refractive index of material of the color filters 222, thereby isolating the adjacent color filters 222 mitigating optical crosstalk to increase the effective size of the color filters 222 (e.g., by directing incident light on both sides of the color filters 222 to the center of the color filters 222). The metal grids may block light, thereby isolating the adjacent color filters 222 and reducing crosstalk. In some embodiments, the metal grids may include, for example, tungsten, copper, or aluminum copper. As shown in FIG. 11, in the present embodiment, microlenses 230 may be further disposed above the composite grid 224 and the color filters 222 to form a backside illuminated image sensor 10.

As the forming steps of the DTI structure 160 shown in FIG. 12, in the present embodiment, by forming the DTI structure 160 after the source/drain implantation and gate formation, high thermal process is allowed to be applied, which can cure and repair damaged trench surfaces of the trench cavity TC caused by the etching processes.

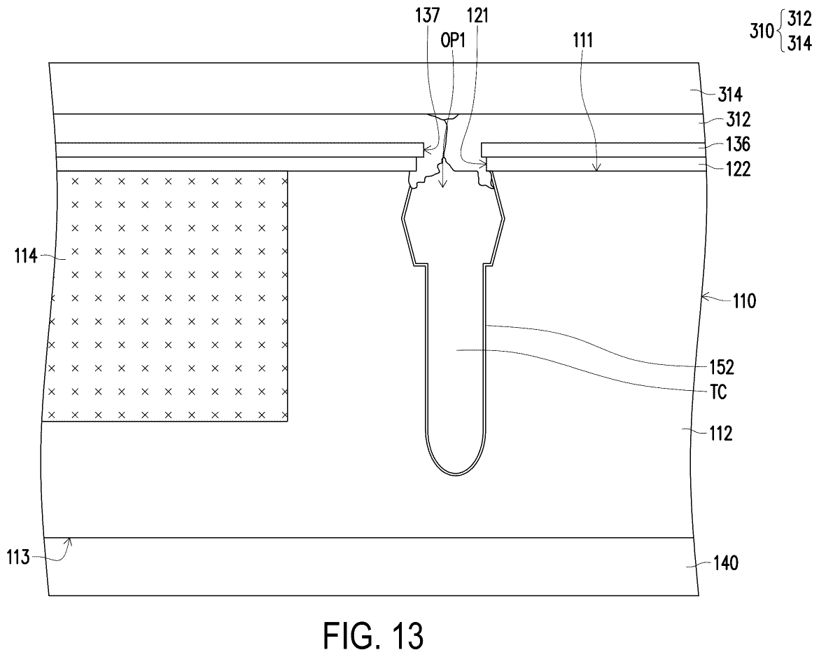

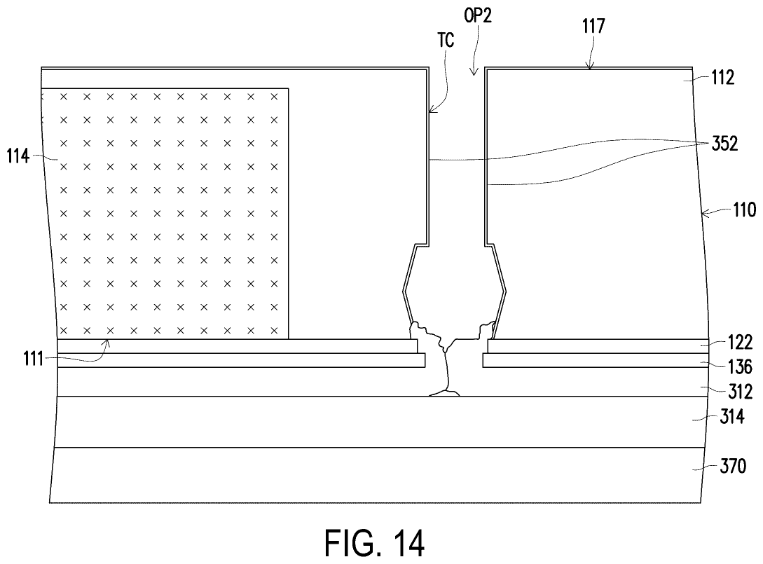

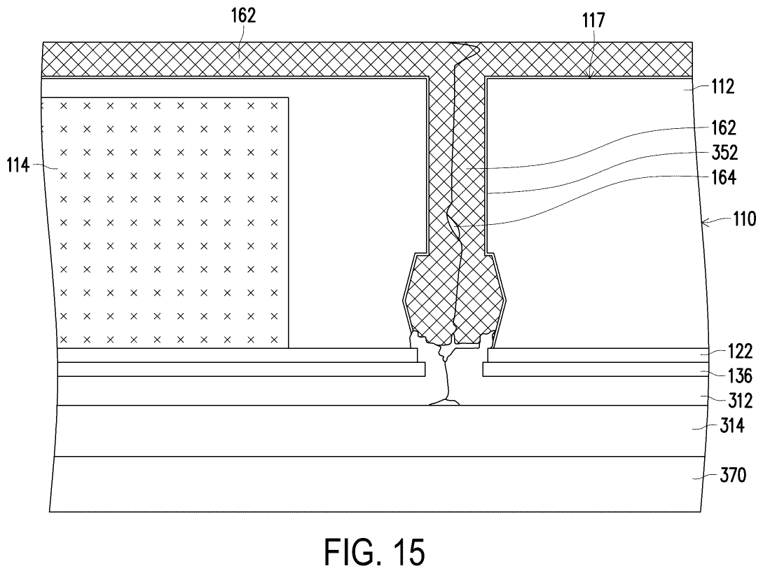

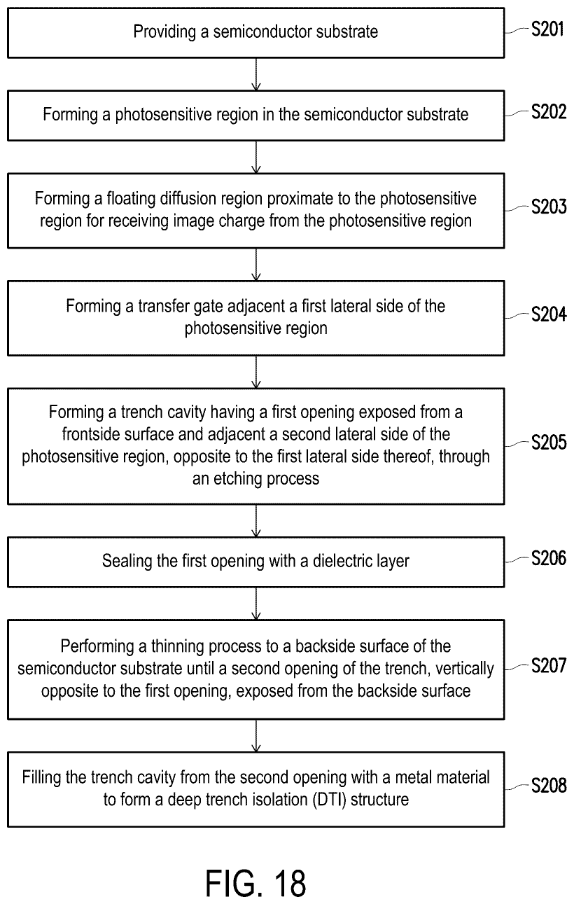

FIG. 13 to FIG. 18 illustrate another embodiment of manufacturing processes after the manufacturing step shown in FIG. 6. FIG. 18 is a schematic block diagram illustrating a formation process of DTI structure in accordance with another embodiment of the present disclosure.

Referring to FIG. 13 and FIG. 18, the forming step S201 to the forming step S204 shown in FIG. 18 are the same or similar to the forming step S101 to the forming step S104 shown in FIG. 13. Accordingly, descriptions for the same or similar formation processes of the DTI structure 160 will not be repeated herein.

Referring to FIG. 13 and the forming steps S205 and S206 shown in FIG. 18, after forming the trench cavity TC and the oxidization layer 152 on the sidewalls thereof as shown in FIG. 6, a first opening OP1 of trench cavity TC, the opening 121 of the HTO layer 122, and the opening 137 of the nitride layer 136 may be sealed by deposition of an IMD 310 layer including an undoped silicon oxide (USG) film 312 deposited though, for example, a plasma-enhanced chemical vapor deposition (PECVD) process. In some embodiments, the IMD layer 310 may further comprise a doped silicon oxide film 314, which may be doped with phosphorous and boron (BPSG) or merely doped with phosphorous (PSG), and deposited on the undoped silicon oxide layer 312 through the PECVD process. In some embodiments, the thickness of the USG film 312 may be approximately 90-120 nm but not limited herein, other desired thickness of the USG film 312 may be also applied based on practical needs in the manufacturing process. In the current embodiment, through deposition of the heavily doped silicon oxide film, doped with, for example, BPSG or PSG, the heavily doped silicon oxide film may serve as a getter for mobile ions.

Referring to FIG. 13 and FIG. 14, the doped silicon oxide film 314 may be polished and subsequently bonded to a substrate 370 including, for example, dielectric layers, layer of hybrid bonds, and an ASIC wafer. As shown in FIG. 13 and FIG. 14 and the forming step S207 in FIG. 18, a thinning process, such as mechanical grinding, wet etching, and CMP process, may be performed to the backside surface 113 of the semiconductor substrate 110 to expose a second opening OP2, vertically opposite to the first opening OP1, of the trench cavity TC. The oxidization layer 152 may be removed through silicon etching or wet etching through HF. In the current embodiment, the sidewalls of the trench cavity TC may be further deposited with a first high κ dielectric layer 352 served as a passivation layer, and the first high κ dielectric layer 352 may also blanketly cover the backside surface 117 of the semiconductor substrate 110 formed after the thinning process.

Referring to FIG. 13 to FIG. 15, the reflective metal material 162, such as Al or Ag, may be filled into the trench cavity TC through the second opening OP2 exposed from the backside surface 117 of the semiconductor substrate 110. A portion of the deposited reflective metal material 162 may blanketly cover the backside surface 117 of the semiconductor substrate 110. In embodiment, referring to FIG. 13 to FIG. 15, a lateral width of second opening OP2 may be smaller than a later width of first opening OP1.

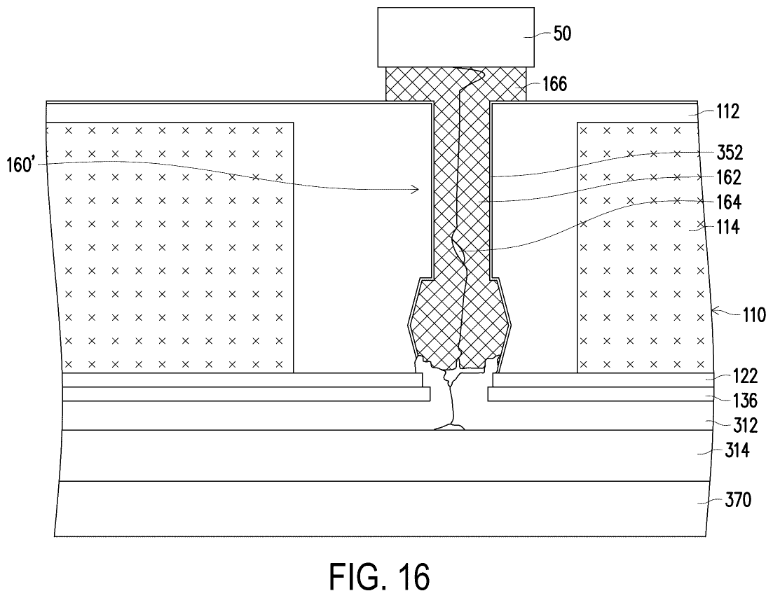

Referring to FIG. 16, a photoresist mask 50 may be deposited on the portion of the reflective metal material 162 covering the backside surface 117 for etching and patterning the reflective metal material 162 and for forming a portion of metal grids 166 connected to the DTI structure 160. In the above etching process, the reflective metal material 162 covers over the photosensitive region 112 is etched and removed to avoid affecting photodiode path/sensitivity. In some embodiments, the above etching process of the reflective metal material 162 may be performed through a combination of dry and wet etching processes for preventing damage to the passivation layer 352.

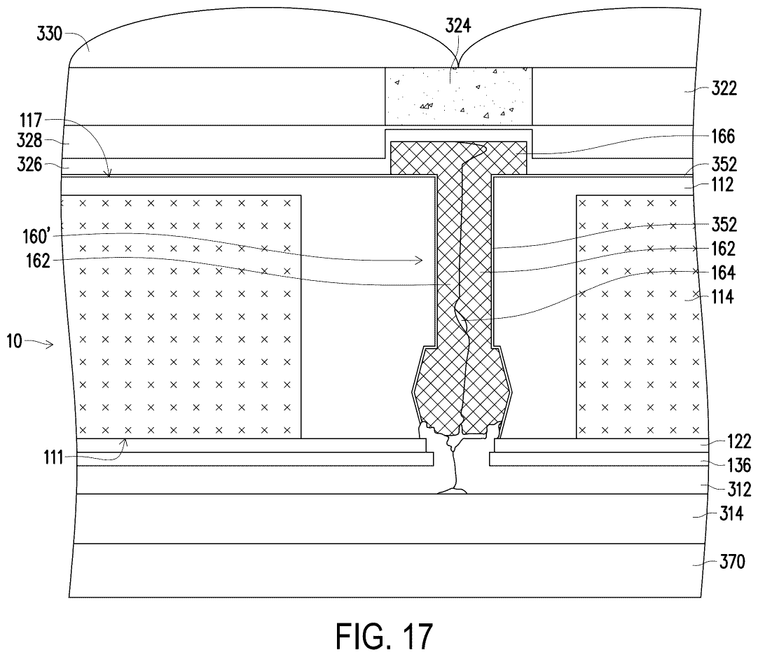

Referring to FIG. 17, another (second) high κ dielectric layer 326 may be disposed on the passivation layer 352 and cover the metal grid 166 to serve as an anti-reflective layer. In some embodiments, as shown in FIG. 17, a buffer oxide layer 328 may be subsequently deposited on the anti-reflective layer 326 for preparation of a backside surface for depositing color filters 322 and composite grids 324 thereon. In some embodiments, the composite grids 324 may include metal grids and low-index (low-n) grids. In some embodiments, the low n grids may include a dielectric, such as silicon oxide (e.g., SiO₂) or hafnium oxide (e.g., HfO₂) or a material having a refractive index smaller than that of the color filters 322. The refractive index of the low n grid is less than the refractive index of the color filters 322, thereby isolating the adjacent color filters 322 and acting as a light guide to increase the effective size of the color filters 322 (e.g., by directing incident light on both sides of the color filters 322 to the center of the color filters 322). The metal grids block light, thereby isolating adjacent color filters 322 and reducing crosstalk. The metal grids may include, for example, tungsten, copper, or aluminum copper.

In the present embodiments, referring to FIG. 17, a portion of the filled reflective metal material 162 extended vertically to and protruded from the backside surface 117 of the semiconductor substrate 110 may serve as a portion of the metal grids 166. As the structure shown in FIG. 13 and FIG. 17, the opening OP1 of the DTI structure 160′ is sealed through the USG film 312 partially filled into the trench cavity TC for subsequent manufacturing process, for example, oxide layer formation. As shown in FIG. 17, the DTI structure 160′ may include at least a process void 164 formed within the filled reflective metal material 162 for releasing inner material strain generated therein during the above deposition process. In the present embodiment, microlenses 330 may be further disposed above the composite grid 324 and the color filters 322 to form the image sensor 10.

In the instant disclosure, referring to FIG. 12 and FIG. 17, the resulted structure of the DTI structures 160, 160′ of the image sensor 10 may respectively formed through frontside filling of the reflective metal material 162 from the opening of the trench cavity TC exposed from the frontside surface 111 of the semiconductor substrate 110 shown in FIG. 6 or formed through backside filling from the opening OP2 exposed from the backside surface 117 of the semiconductor substrate 110 shown in FIG. 14. The frontside filling process and the backside filling process may be applied and performed based on availabilities of fabrication equipment in different manufacturing facilities. In both manufacturing processes, the DTI structures 160, 160′ are formed after formation of the implanted source and drain regions, the transfer gate, and floating diffusion regions. Hence, the high thermal process can be applied to DTI structure 160, 160′ to cure and repair damage of the trench surfaces caused by the etching processes.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A manufacturing method of an image sensor comprising:
providing a semiconductor substrate having a frontside surface and a backside surface opposite to the frontside surface;
forming a photosensitive region in the semiconductor substrate;
forming a floating diffusion region proximate to the photosensitive region for receiving image charge therefrom;
forming a dielectric layer on the frontside surface of the semiconductor substrate;
forming a gate electrode in the dielectric layer that electrically couples to the photosensitive region and the floating diffusion region; and
forming a deep trench isolation (DTI) structure adjacent to the photosensitive region, wherein the DTI structure extends from the dielectric layer on the frontside surface toward the backside surface of the semiconductor substrate, wherein the DTI structure has an upper surface leveled with a top surface of the dielectric layer.

2. The method according to claim 1, wherein at least a process void is formed in the DTI structure within a reflective metal material.

3. The method according to claim 2, wherein the reflective metal material comprises aluminum or silver.

4. The method according to claim 1, wherein the step of formation of DTI structure comprises forming a trench cavity extending from the dielectric layer on the frontside surface toward the backside surface of the semiconductor substrate through the etching process, wherein an oxidization layer is formed on sidewalls of the trench cavity through a thermal oxidization process, wherein the trench cavity has an opening at the top surface of the dielectric layer on the frontside surface, and a reflective metal material is deposited into the trench cavity from the opening.

5. The method according to claim 4, further comprising bonding the semiconductor substrate to a wafer substrate after formation of the trench cavity.

6. The method according to claim 5, wherein, prior to the formation of the trench cavity, the step of forming the dielectric layer on the frontside surface of the semiconductor substrate comprises:
forming a portion of the dielectric layer on the frontside surface of the semiconductor substrate encapsulating the gate electrode; and
depositing a nitride layer on the dielectric layer, wherein the dielectric layer comprises a high thermal oxide layer.

7. The method according to claim 1, further comprising forming spacers enclosing outer sidewalls of the gate electrode.

8. The method according to claim 1, further comprising performing a thinning process to the backside surface of the semiconductor substrate after formation of the DTI structure to expose a tip portion of the DTI structure from the backside surface.

9. The method according to claim 1, further comprising forming an intermetallic dielectric (IMD) layer on the frontside surface of the semiconductor substrate and encapsulating the gate electrode.

10. The method according to claim 9, further comprising bonding a logic wafer to the IMD layer.

11. A manufacturing method of an image sensor, comprising:
providing a semiconductor substrate having a frontside surface and a backside surface opposite to the frontside surface;
forming a photosensitive region in the semiconductor substrate;
forming a floating diffusion region proximate to the photosensitive region for receiving image charge therefrom;
forming a transfer gate adjacent to the photosensitive region;
forming a dielectric layer on the frontside surface of the semiconductor substrate;
etching through the dielectric layer and the semiconductor substrate to form a trench cavity adjacent to the photosensitive region, wherein the trench cavity has a first opening on the frontside surface and extends from the frontside surface toward the backside surface of the semiconductor substrate;
sealing the first opening of the trench cavity on the frontside surface with an undoped silicon oxide layer;
performing a thinning process to the backside surface of the semiconductor substrate until a second opening of the trench cavity, vertically opposite to the first opening, exposed from the backside surface; and
filling the trench cavity with a reflective metal material from the second opening to form a deep trench isolation (DTI) structure in the semiconductor substrate.

12. The method according to claim 11, further comprising depositing a high κ dielectric passivation layer on sidewalls of the trench cavity prior to filling the reflective metal material into the trench cavity.

13. The method according to claim 11, further comprising depositing a doped silicon oxide layer on the undoped silicon oxide layer.

14. The method according to claim 13, wherein the doped silicon oxide layer is doped with phosphorus or combination of phosphorus and boron.

15. The method according to claim 11, wherein a portion of the reflective metal material is protruded out from the second opening and covers the backside surface of the semiconductor substrate, wherein a patterning etch process is performed to the portion of the reflective metal material for forming a portion of metal grids over the DTI structure.

16. An image sensor, comprising:
a semiconductor substrate having a frontside surface and a backside surface opposite to the frontside surface;
a photosensitive region disposed in the semiconductor substrate;
a gate electrode disposed adjacent to a lateral side of the photosensitive region;
a floating diffusion proximate to the photosensitive region to receive image charge from the photosensitive region;
a dielectric layer having a first opening disposed on the frontside surface of the semiconductor substrate; and
a deep trench isolation (DTI) structure disposed adjacent to the photosensitive region, wherein the DTI structure is disposed aligning with the first opening of the dielectric layer and extends through the semiconductor substrate, wherein the DTI structure is filled with a reflective metal material layer.

17. The image sensor according to claim 16, wherein the DTI structure comprises a second opening exposed from the frontside surface of the semiconductor substrate, wherein the second opening of the DTI structure is aligned with the first opening of the dielectric layer and sealed with an undoped silicon oxide layer.

18. The image sensor according to claim 17, wherein the DTI structure comprises a third opening exposed from the backside surface of the semiconductor substrate, wherein the reflective metal material is protruded outward from the third opening for forming a portion of metal grids on the backside surface of the semiconductor substrate.

19. The image sensor according to claim 16, wherein an upper surface of a portion of the reflective metal material filled in the first opening of the dielectric layer is leveled with an upper surface of the dielectric layer, wherein the dielectric layer comprises at least one of a high thermal oxide layer and a nitride layer.

20. The image sensor according to claim 16, further comprising a contact disposed in an intermetallic dielectric layer on the dielectric layer, wherein the contact is coupled to the DTI structure to receive a bias voltage.
